(19) United States
(12) Patent Application Publication
(10) Pub. No.: US 2009/0087794 A1
(43) Pub. Date: Apr. 2, 2009

(54) METHOD FOR MANUFACTURING DIFFRACTIVE OPTICAL ELEMENT

(75) Inventors: Ryo Sekikawa, Tokyo (JP); Yoshinori Maeno, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/913,074

(22) PCT Filed: May 2, 2005
(86) PCT No.: PCT/JP2005/008285

§ 371 Date: Oct. 30, 2007

(51) Int. Cl. G03F 7/20

(52) U.S. Cl. 430/321

(57) ABSTRACT

Object To provide a diffractive optical element manufacturing method through which a high-precision diffractive optical element is formed to assure an improvement in the diffraction efficiency.

Means for Solving the Problems A diffractive optical element assuming cyclical stage patterns is manufactured through a procedural sequence of steps of exposing and developing a substrate 1 with a resist 2 applied thereupon by using a mask to form a resist pattern and then repeatedly etching the substrate by using resist pattern. In a first process, a pattern defining widths matching the widths of the stages to be formed is formed and greater pattern widths are set for subsequent processes. When manufacturing a diffractive optical element with seven-stage patterns, for instance, the areas to form the second, fourth and sixth stages are etched to a depth D representing the stage depth through the first process, the area to form the ninth stage is etched to a depth 2D through a second process, the area to form the fifth, sixth and seventh stages is etched to the depth 2D through a third process and the area to form the third, fourth, fifth, sixth and seventh stages is etched to the depth 2D through a fourth process.

### TECHNICAL FIELD

The present invention relates to a method to be adopted when manufacturing a diffractive optical element assuming a staged shape.

### BACKGROUND ART

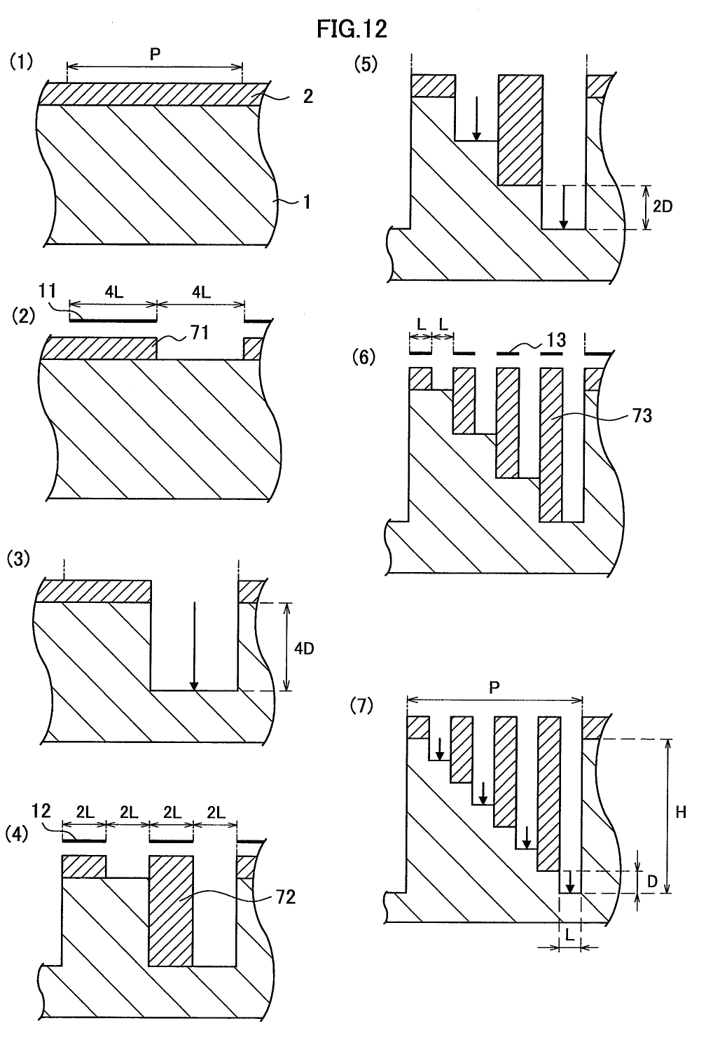

The demand for diffractive optical elements that control the light advancing direction and the phase by assuming cyclical fine patterns has increased in recent years. While there are a number of different shapes that such diffractive optical elements may adopt and the shape with a sawtooth section among them assures a high level of diffraction efficiency in theory, diffractive optical elements with a staged shape approximating the sawtooth shape, which can be manufactured with greater ease, are in wide use. The methods often adopted when manufacturing diffractive optical elements with staged shapes include the one disclosed in non-patent reference literature 1, whereby a procedural sequence of steps such as exposure, development and etching is repeatedly executed by using m (m represents a natural number) masks through a semiconductor microprocessing technology to manufacture a diffractive optical element with 2^{m} stage patterns. For instance, a sequence that includes an exposure step, a development step and an etching step is executed three times by using three masks to manufacture a diffractive optical element with eight stages. The manufacturing steps executed by adopting this method are explained in reference to FIG. 12.

In the following explanation, the width representing the cycle over which the stages are formed is referred to as P, the width of a stage formed through the final process is referred to as L and the stage depth is referred to as D. The range of the cyclical width P, which is the lattice pitch P, is indicated by the one-point chain lines in the figures. It is assumed that all the stages have a uniform width L=P/k. k represents the number of stages, and, for instance, if the diffractive optical element has eight stages per cycle, k=8. In addition, with H representing the height achieved with the entire set of stages, the stage depth is expressed as D=H/(k−1). FIG. 12(7) shows the stages that are finally formed, labeled with P, L, D and H.

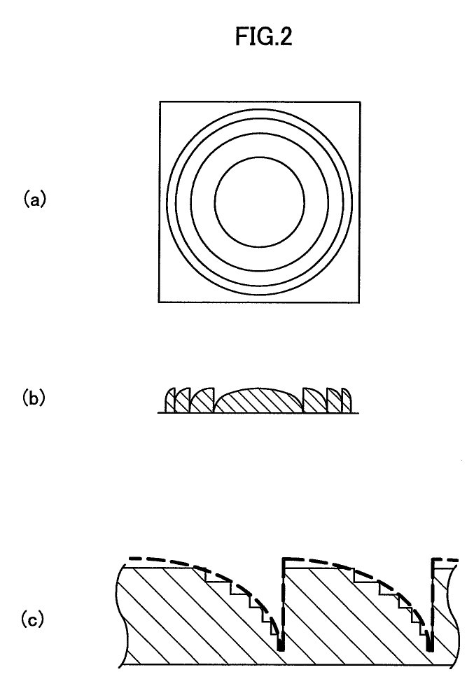

FIG. 12 show the manufacturing steps executed in various processes in FIG. 2(c). A first process starts as a resist 2 is applied onto a substrate 1, as shown in FIG. 12(1). Next, the substrate is exposed and developed by using a mask 11, as shown in FIG. 12(2) and, as a result, a resist pattern 71 shown in FIG. 12(2) is formed. One light shielding portion and one opening portion are formed within each lattice pitch P in the mask 11 and the pattern widths of the light shielding portion and the opening portion are both 4L. Next, the substrate is etched to a depth 4D by using the resist pattern 71 so as to form a groove, as shown in FIG. 12(3). The resist pattern 71 is then removed.

The operation then shifts into a second process. A resist is first applied onto the substrate with the grooves having been formed therein through the first process. Next, the substrate is exposed and developed by using a mask 12, as shown in FIG. 12(4) and, as a result, a resist pattern 72 shown in FIG. 12(4) is formed. Two light shielding portions and two opening portions are formed within each lattice pitch P in the mask 12 and the pattern widths of the individual light shielding portions and the individual opening portions are 2L. Next, the substrate is etched to a depth 2D by using the resist pattern 72 so as to form grooves, as shown in FIG. 12(3). The resist pattern 72 is then removed.

The operation then shifts into a third process. A resist is first applied onto the substrate with the grooves having been formed therein through the second process. Next, the substrate is exposed and developed by using a mask 13, as shown in FIG. 12(6) and, as a result, a resist pattern 73 shown in FIG. 12(6) is formed. Four light shielding portions and four opening portions are formed within each lattice pitch P in the mask 13 and the pattern widths of the individual light shielding portion and the individual opening portions are L. Next, the substrate is etched to a depth D by using the resist pattern 73 so as to form grooves, as shown in FIG. 12(7). Then, a diffractive optical element with eight stages is obtained by removing the resist pattern 73.

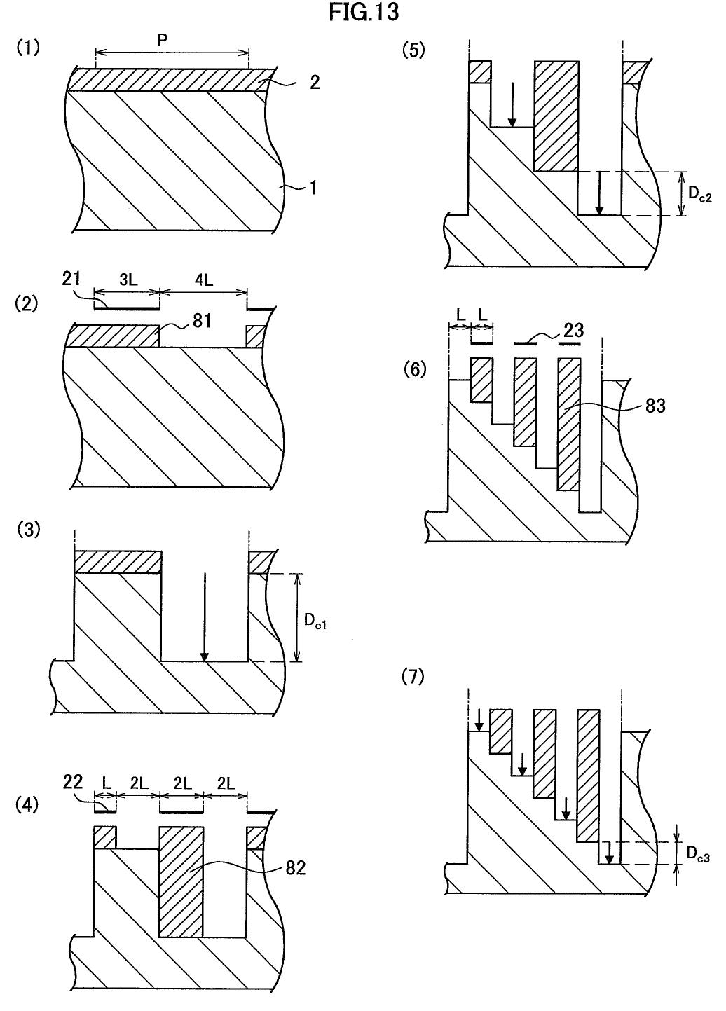

In addition, patent reference literature 1 cited below discloses a method for manufacturing a diffractive optical element with seven stages by repeatedly executing similar processes with three masks. The manufacturing steps executed in this method are now explained in reference to FIG. 13. In the following description given by assuming that k=7, P, L and D have definitions identical to those explained earlier.

FIG. 13 show the manufacturing steps executed in various processes in FIG. 2(c). A first process starts as a resist 2 is applied onto a substrate 1, as shown in FIG. 13(1). Next, the substrate is exposed and developed by using a mask 21, as shown in FIG. 13(2) and, as a result, a resist pattern 81 shown in FIG. 13(2) is formed. One light shielding portion and one opening portion are formed within each lattice pitch P in the mask 21 and the pattern width of the light shielding portion and the opening portion are respectively 3L and 4L. Next, the substrate is etched by using the resist pattern 81 so as to form a groove, as shown in FIG. 13(3). The etching depth Dc₁ achieved through the first process is 4D. The resist pattern 81 is then removed.

The operation then shifts into a second process. A resist is first applied onto the substrate with the groove having been formed therein through the first process. Next, the substrate is exposed and developed by using a mask 22, as shown in FIG. 13(4) and, as a result, a resist pattern 82 shown in FIG. 13(4) is formed. Two light shielding portions and two opening portions are formed within each lattice pitch P in the mask 22, the pattern widths of the upper stage-side light shielding portion and the lower stage-side light shielding portion are respectively L and 2L, and the pattern widths of the two opening portions are each 2L. Next, the substrate is etched by using the resist pattern 82 so as to form grooves, as shown in FIG. 13(5). The etching depth Dc₂ achieved through the second process is 2D. The resist pattern 82 is then removed.

The operation then shifts into a third process. A resist is first applied onto the substrate with the grooves having been formed therein through the second process. Next, the substrate is exposed and developed by using a mask 23, as shown in FIG. 13(6) and, as a result, a resist pattern 83 shown in FIG. 13(6) is formed. Three light shielding portions and four opening portions are formed within each lattice pitch P in the mask 23 and the pattern widths of the individual light shielding portions and the individual opening portions are all L. Next, the substrate is etched by using the resist pattern 83 so as to form grooves, as shown in FIG. 13(7). The etching depth Dc₃ achieved through the third process is D. Then, a diffractive optical element with seven stages is obtained by removing the resist pattern 83.

### (Non-Patent Reference Literature 1)

“High-Accuracy Mounting Technologies/Light Sources And Silicon Micro-Lenses” Electronics Mounting Conference Periodical 2002, vol. 5, No. 5, pp 466-472, by Hironori Sasaki and six others

### (Patent Reference Literature 1)

Japanese Laid Open Patent Publication No. H11-14813

### DISCLOSURE OF THE INVENTION

### Problems to be Solved by the Invention

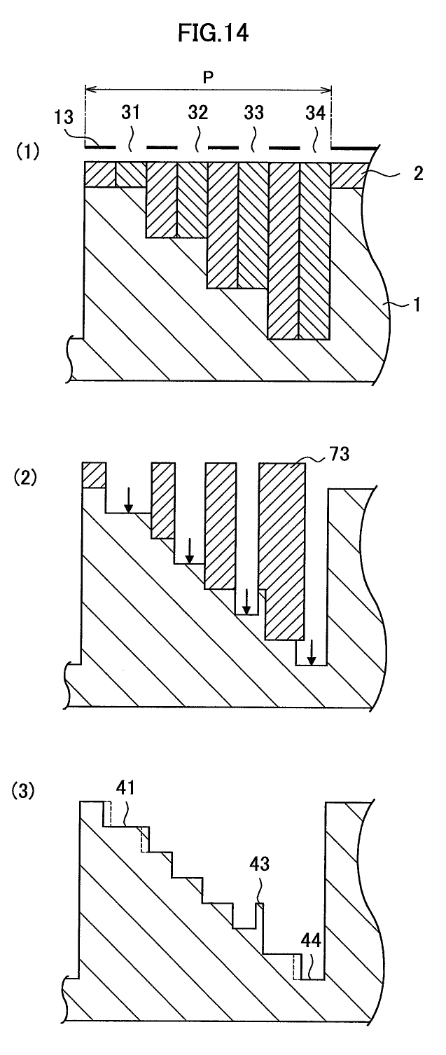

In the methods for manufacturing staged diffractive optical elements in the related art described above, the masks used in later steps assume smaller pattern widths. In other words, greater numbers of light shielding portions and opening portions are formed within each lattice pitch P with a greater number of boundaries separating the light shielding portions and the opening portions. In addition, as the further steps are executed, the number of stages formed at the substrate increases. FIG. 14(1) is a sectional view of the exposure step executed in the third process shown in FIG. 12. In FIG. 14(1), the light shielding portions and the exposure target areas in the resist 2 are shaded with lines with the diagonal lines tilting along different directions so as to indicate them in a distinguishable manner. As shown in FIG. 14(1), four areas 31, 32, 33 and 34 are exposed through the third process, executed by using the mask 13, within the lattice pitch P, with seven boundaries separating the light shielding portions from the opening portions. The various exposure target areas correspond to different stages and thus, the resist is applied over them with varying thicknesses. FIG. 14(2) presents an example of the resist pattern 73 obtained by exposing and developing the substrate shown in FIG. 14(1). The resist pattern 73 having been formed does not exactly match the mask pattern over the boundaries with the light shielding portions, since the resist is applied onto the substrate with varying thicknesses in correspondence to the individual stages and thus, the optimal exposure conditions for the four exposure target areas are different. At the exposure target area 31 exposed over a length of time exceeding its optimal exposure time more resist is removed from the adjacent light shielding portion, resulting the exposed area assuming a greater pattern width than the design value. At the exposure target areas 33 and 34, which are not exposed over their optimal exposure time lengths, more resist remains unexposed to result in smaller pattern widths than the design value. FIG. 14(3) is a sectional view of the substrate from which the resist pattern 73 shown in FIG. 14(2) has been removed after the etching process executed by using the resist pattern 73. In FIG. 14(3), the shape that should have been achieved in conformance to the design value is indicated by the dotted lines and the shape that has actually been achieved is indicated by the solid lines. As shown in FIG. 14(3), a stage 41 with a greater width than the design value has been formed over an area corresponding to the exposure target area 31. In addition, over an area corresponding to the exposure target areas 33 and 34, a projection 43 has been formed at the edge of a stage shape and a stage 4 having been formed assumes a width smaller than the design value. This means that there is an issue to be addressed in the manufacturing methods in the related art in that stages with dimensions different from the design value or a projection formed at an edge may lower the diffraction efficiency.

Accordingly, an object of the present invention, having been completed by addressing the problems discussed above, is to provide a new and improved method for manufacturing a diffractive optical element, through which a diffractive optical element having stage patterns can be manufactured with a high level of accuracy.

### Means for Solving the Problems

The object described above is achieved in an aspect of the present invention by providing a method for manufacturing a diffractive optical element having a cyclical stage pattern with k (k represents a natural number equal to or greater than 2) stages through a process of repeatedly etching the surface of a substrate by using a resist pattern. The number of etching target areas and the number of non-etching areas set in a single cycle area for a first process are both k/2 if k is an even number, but the number of etching target areas and the number of non-etching areas set in the single cycle area for the first process are respectively (k−1)/2 and (k+1)/2 if k is an odd number. The number of etching target areas to be etched through a second and subsequent processes and the number of non-etching areas present in the single cycle area are both smaller than the number of etching target areas and the number of non-etching areas set for the first process. The term “single cycle area” refers to an area used to form a stage pattern and it excludes any area that is not relevant to the formation of the stage pattern. The term “etching target area” refers to an area that is etched through an etching step, whereas the term “non-etching area” refers to an area that remains unetched through the etching step. Regardless of the correspondence to the stages being formed, a continuous etching target area present within the single cycle area is regarded as a single etching target area and a continuous non-etching area present within the single cycle area is regarded as a single non-etching area. The resist pattern is a pattern constituted with resist removal areas and resist retaining areas. As the surface of a substrate with such a resist pattern formed thereupon is etched, the resist removal areas are etched but the resist retaining areas remain unetched. Thus, by using a specific resist pattern, specific areas can be selectively etched. This means that the numbers of etching target areas and non-etching areas directly correspond to the numbers of resist removal areas and resist retaining areas. Generally speaking, the variance among the resist thicknesses at the individual stages becomes more pronounced in a later step, which tends to result in an error in the shape of the resist pattern. Such an error occurs at a boundary separating a resist removal area from a resist retaining area. According to the present invention, the single cycle area contains the greatest numbers of etching target areas and non-etching areas during the first process and the numbers become smaller in the later processes. The numbers of resist removal areas and resist retaining areas in the single cycle area, too, are the greatest during the first process and become smaller in the later processes. The number of boundaries between the resist removal areas and the resist retaining areas is the greatest during the first process and becomes smaller in the later processes. Namely, according to the present invention, the number of boundaries over which an error tends to occur readily is reduced in the later steps in which the variance among the resist thicknesses among the individual stages becomes more pronounced. As a result, the error is reduced and a diffractive optical element assuming stage patterns can be manufactured with a high level of accuracy.

It is desirable that the numbers of etching target areas and non-etching areas set in the single cycle area for the second process and subsequent process executed in the manufacturing method described above both be one. According to this method, there will only be one boundary area separating the resist removal area from the resist retaining area during the second and subsequent processes through which more stages are formed. Since there is only one area where the resist pattern error factor described above needs to be taken into consideration and the exposure conditions can be determined simply to prevent an error from occurring over this specific area, optimal conditions can be set with ease.

In another aspect of the present invention, a method for manufacturing a diffractive optical element assuming a cyclical stage pattern through a process of etching the surface of a substrate repeatedly by using a resist patterns is provided. The manufacturing method is characterized in that the pattern widths of etching target areas set in a single cycle area for a first process substantially match a smallest stage width. The term “smallest stage width” refers to the width of a stage assuming the smallest width if the stages that are ultimately formed are to have varying widths, whereas the term “smallest stage width” refers to the width of each stage if the widths of the stages that are ultimately formed are to be equal to one another. Generally speaking, the overall depth of the stage patterns increases and the variance among the resist thicknesses at the individual stages becomes more pronounced in later steps. For this reason, it is more difficult to define the smallest pattern width with a high level of accuracy in the later steps. According to the present invention, the area to assume the smallest pattern width is defined through etching during the first process. Since the resist applied to the flat substrate surface at the start of the first process assumes a uniform resist thickness, it is easier to accurately define the smallest pattern width at this phase.

In yet another aspect of the present invention, a method for manufacturing a diffractive optical element with seven stage patterns through a process of etching the surface of a substrate repeatedly by using a resist pattern, comprising a first step in which an area to form a second stage, a fourth stage and a sixth stage are etched to a first depth representing a stage depth, a second step in which an area to form a lowest stage is etched to a depth twice the first depth, a third step in which an area to form a fifth stage, the sixth stage and the seventh stage is etched to a depth twice the first depth and a fourth step in which an area to form a third stage, the fourth stage, the fifth stage, the sixth stage and the seventh stage is etched to a depth twice the first depth, is provided. It is to be noted that the uppermost stage is referred to as a first stage and the lower stages are sequentially referred to as the second stage, the third stage and so forth. According to this method, the smallest pattern width can be set for the first step and greater pattern widths can be set for later steps. Since a greater pattern width is used in a later step in which the overall depth of the stage patterns is greater and the variance among the resist thicknesses at the individual stages becomes more pronounced, an error does not occur readily in the resist pattern shape. A diffractive optical element with stage patterns can thus be manufactured with a high level of accuracy.

In yet another aspect of the present invention, a method for manufacturing a diffractive optical element with nine stage patterns through a process of etching the surface of a substrate repeatedly by using a resist pattern, comprising a first step in which an area to form a second stage, a fourth stage, a sixth stage and an eighth stage are etched to a first depth representing a stage depth, a second step in which an area to form a lowest stage is etched to a depth twice the first depth, a third step in which an area to form a third stage, the fourth stage, a seventh stage, the eighth stage and a ninth stage is etched to a depth twice the first depth and a fourth step in which an area to form a fifth stage, the sixth stage, the seventh stage, the eighth stage and the ninth stage is etched to a depth four times the first depth, is provided.

In yet another aspect of the present invention, a method for manufacturing a diffractive optical element with eight stage patterns through a process of etching the surface of a substrate repeatedly by using a resist pattern, comprising a first step in which an area to form a second stage, a fourth stage, a sixth stage and an eighth stage are etched to a first depth representing a stage depth, a second step in which an area to form a seventh stage and the eighth stage is etched to a depth twice the first depth, a third step in which an area to form a fifth stage, the sixth stage, the seventh stage and the eighth stage is etched to a depth twice the first depth and a fourth step in which an area to form a third stage, the fourth stage, the fifth stage, the sixth stage, the seventh stage and the eighth stage is etched to a depth twice the first depth, is provided.

In yet another aspect of the present invention, a method for manufacturing a diffractive optical element with five stage patterns through a process of etching the surface of a substrate repeatedly by using a resist pattern, comprising a first step in which an area to form a second stage and a fourth stage are etched to a first depth representing a stage depth, a second step in which an area to form a lowest stage is etched to a depth twice the first depth and a third step in which an area to form a third stage, the fourth stage and a fifth stage is etched to a depth twice the first depth, is provided.

In yet another aspect of the present invention, a method for manufacturing a diffractive optical element with seven stage patterns through a process of etching the surface of a substrate repeatedly by using a resist pattern, comprising a first step in which an area to form the lowest stage is etched to a first depth twice the stage depth, a second step in which an area to form a second stage, a fourth stage and a sixth stage are etched to a second depth matching the stage depth, a third step in which an area to form a fifth stage, the sixth stage and a seventh stage is etched to the first depth and a fourth step in which an area to form a third stage, the fourth stage, the fifth stage, the sixth stage and the seventh stage is etched to the first depth, is provided.

In yet another aspect of the present invention, a method for manufacturing a diffractive optical element with nine stage patterns through a process of etching the surface of a substrate repeatedly by using a resist pattern, comprising a first step in which an area to form a lowest stage is etched to a first depth twice the stage depth, a second step in which an area to form a second stage, a fourth stage, a sixth stage and an eighth stage are etched to a second depth matching the stage depth, a third step in which an area to form a third stage, the fourth stage, a seventh stage, the eighth stage and a ninth stage are etched to the first depth and a fourth step in which an area to form a fifth stage, the sixth stage, the seventh stage, the eighth stage and the ninth stage is etched to a depth twice the first depth, is provided.

In yet another aspect of the present invention, a method for manufacturing a diffractive optical element with fife stages through a process of etching the surface of a substrate repeatedly by using a resist pattern, comprising a first step in which an area to form the lowest stage is etched to a first depth twice the stage depth, a second step in which an area to form a second stage and a fourth stage are etched to a second depth matching the stage depth and a third step in which an area to form a third stage, the fourth stage and the fifth stage are etched to the first depth, is provided.

It is desirable that the substrate be etched through anisotropic etching in all the manufacturing methods described above. The substrate may be constituted of silicon, quartz, GaAs or InP.

### EFFECT OF THE INVENTION

By adopting any of the diffractive optical element manufacturing methods according to the present invention described above, a diffractive optical element assuming a stage pattern can be manufactured with a high level of accuracy and, as a result, an improvement in the diffraction efficiency is achieved.

### BRIEF DESCRIPTION OF THE DRAWINGS

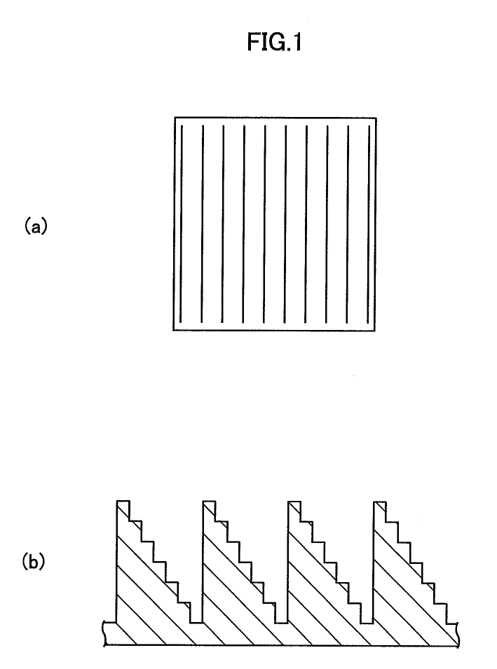

(FIG. 1) A schematic illustration presenting an example of a diffractive optical element

(FIG. 2) A schematic illustration presenting an example of a diffractive optical element

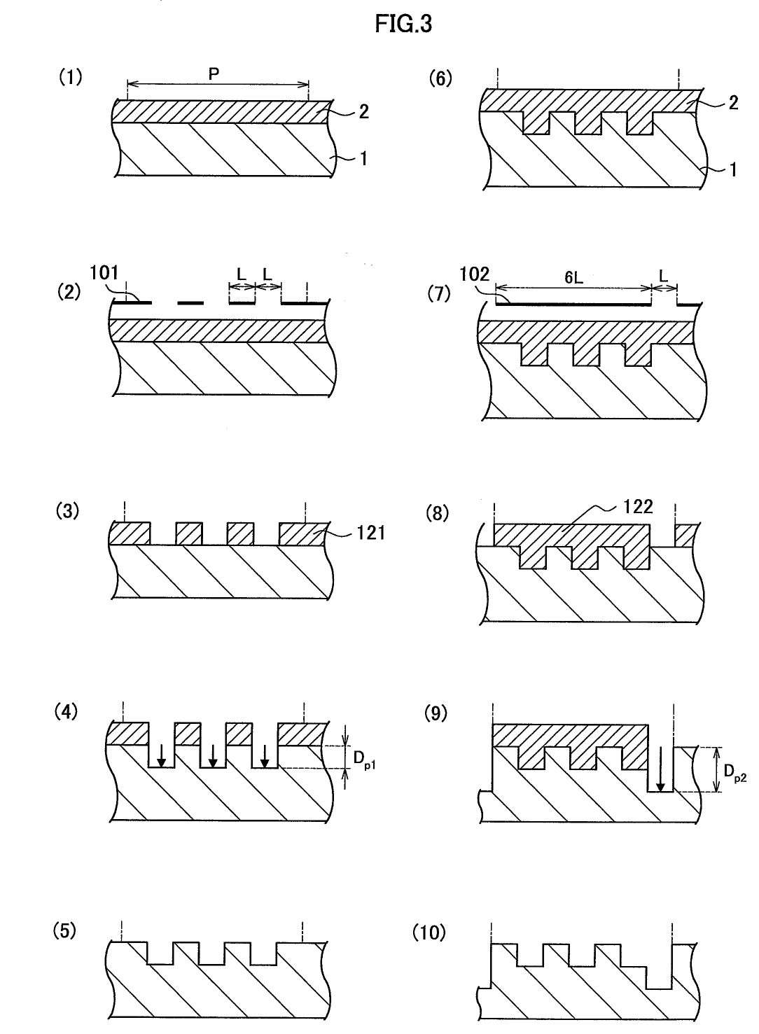

(FIG. 3) A sectional view illustrating a step executed in the diffractive optical element manufacturing method achieved in a first embodiment of the present invention

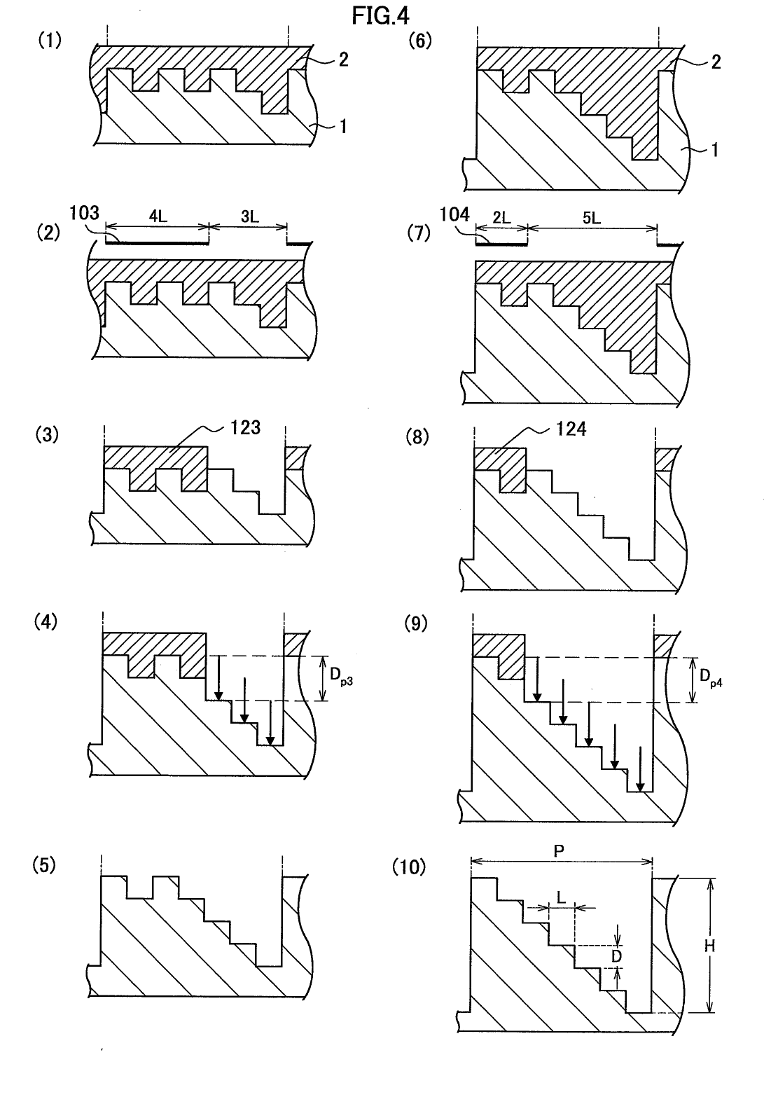

(FIG. 4) Illustrates a step executed after the step shown in FIG. 3

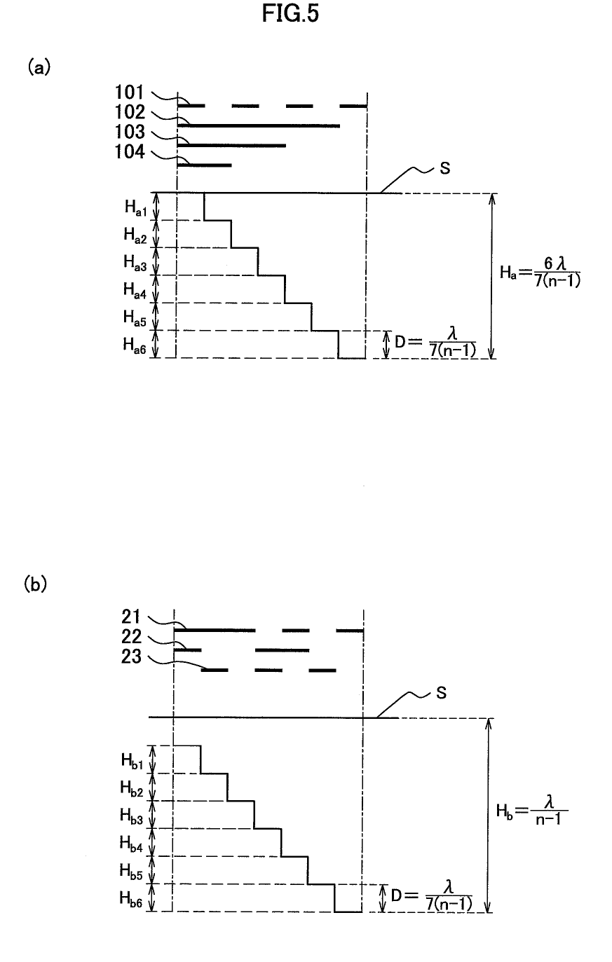

(FIG. 5) Illustrates a method that may be adopted when determining the method through which a diffractive optical element was manufactured

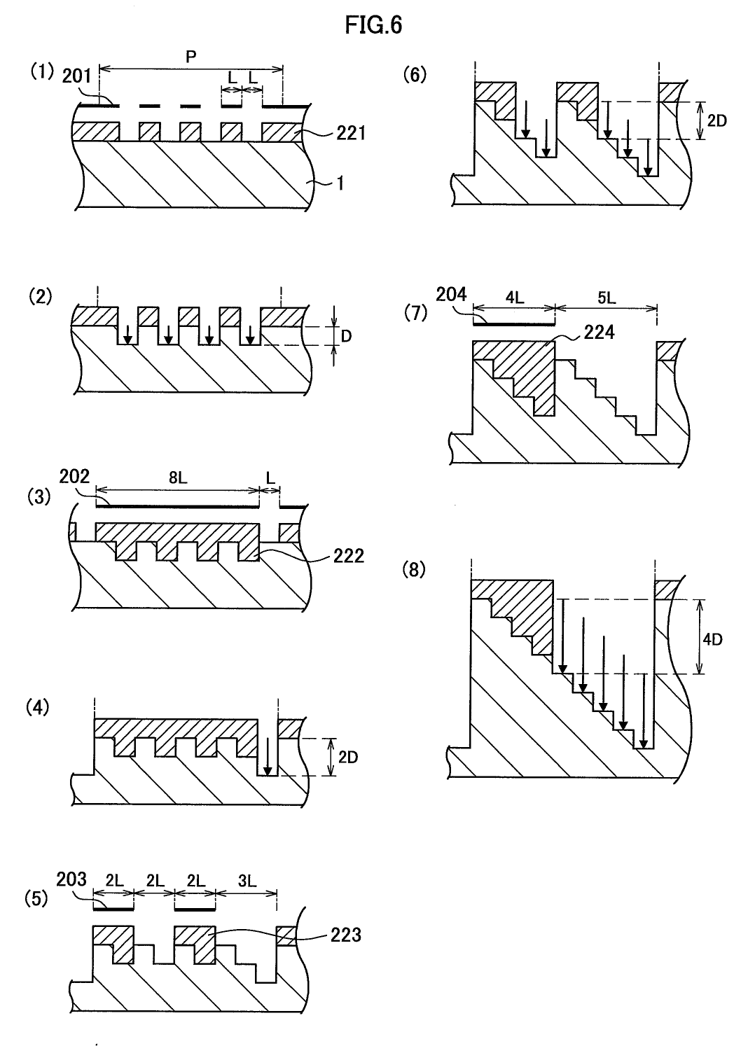

(FIG. 6) A sectional view illustrating a step executed in the diffractive optical element manufacturing method achieved in a second embodiment of the present invention

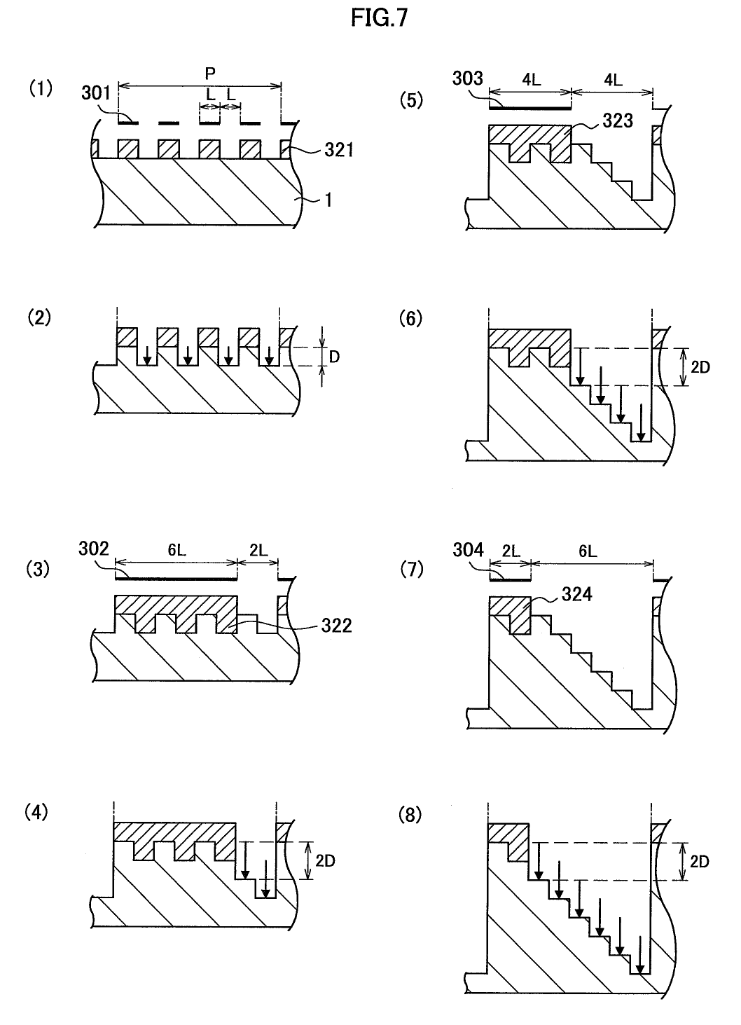

(FIG. 7) A sectional view illustrating a step executed in the diffractive optical element manufacturing method achieved in a third embodiment of the present invention

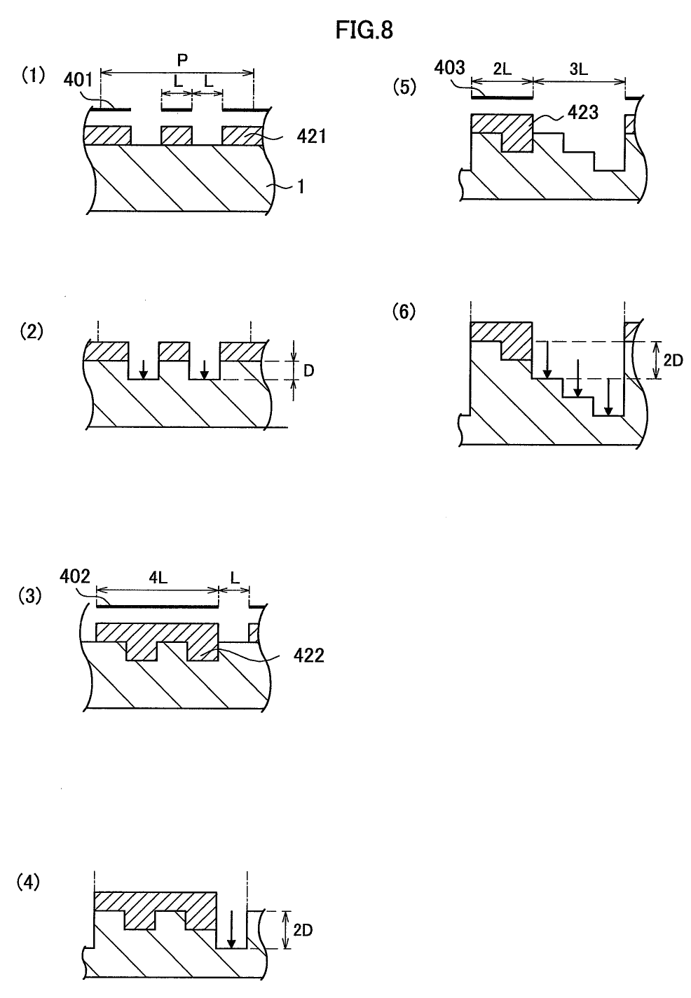

(FIG. 8) A sectional view illustrating a step executed in the diffractive optical element manufacturing method achieved in a fourth embodiment of the present invention

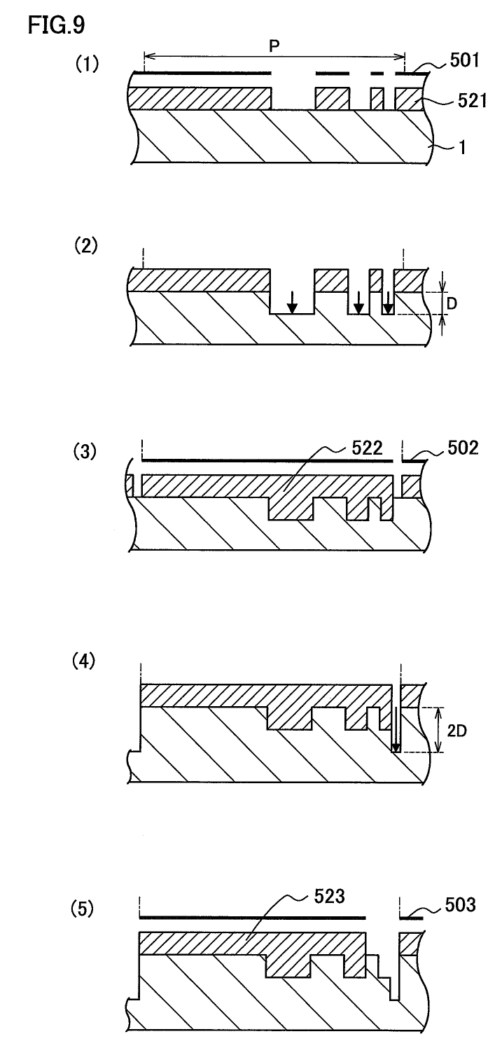

(FIG. 9) A sectional view illustrating a step executed in the diffractive optical element manufacturing method achieved in a fifth embodiment of the present invention

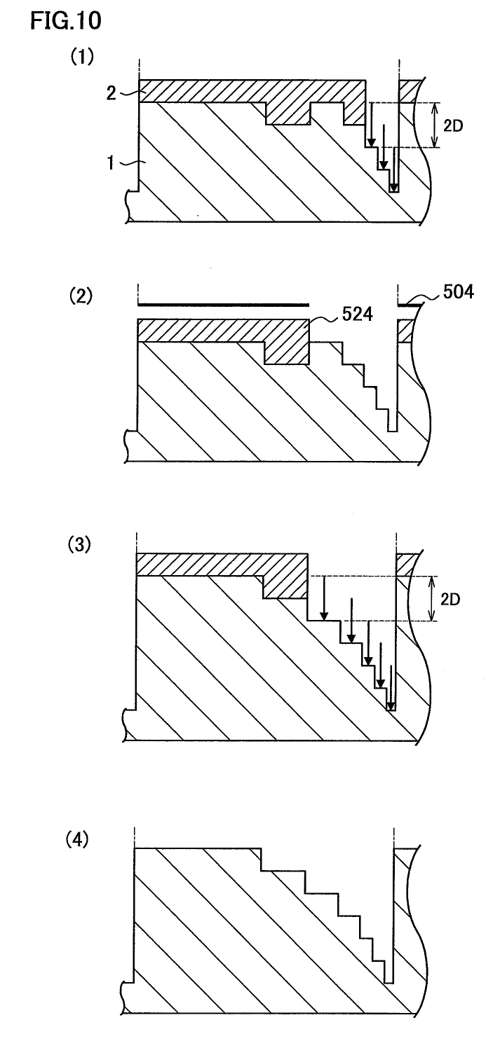

(FIG. 10) Illustrates a step executed after the step shown in FIG. 9

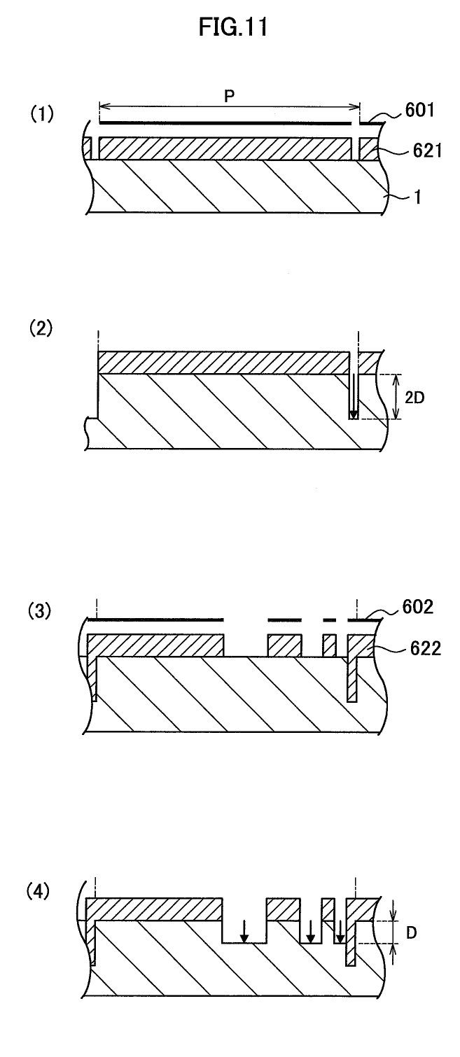

(FIG. 11) A sectional view illustrating a step executed in the diffractive optical element manufacturing method achieved as a variation of the present invention

(FIG. 12) A sectional view illustrating a step executed in a diffractive optical element manufacturing method in the related art

(FIG. 13) A sectional view illustrating a step executed in a diffractive optical element manufacturing method in the related art

(FIG. 14) The issues to be addressed in the diffractive optical element manufacturing methods in the related art

### EXPLANATION OF REFERENCE NUMERALS

1 substrate
2 resist
11, 12, 13, 14 mask
101, 102, 103, 104 mask

### BEST MODE FOR CARRYING OUT THE INVENTION

The following is a detailed explanation of preferred embodiments of the present invention given in reference to the attached drawings. It is to be noted that in the description and the drawings, the same reference numerals are assigned to components assuming substantially identical functions and structural features to preclude the necessity for a repeated explanation thereof.

In the diffractive optical element manufacturing method achieved in the embodiments of the present invention, diffractive optical elements assuming a cyclical stage patterns are manufactured through a sequence of processes, executed repeatedly by adopting a semiconductor microprocessing technology. During the processing sequence, a resist is applied onto a substrate, the substrate is exposed and developed by using a mask with a specific pattern formed therein so as to form a resist pattern constituted with resist removal areas and resist retaining areas and then the substrate is etched by using the resist pattern.

It is to be noted that FIG. 1 and FIG. 2 present schematic illustrations of two examples of diffractive optical elements among many different types of diffractive optical elements. FIG. 1 show a diffractive optical element constituted with a diffraction grating array assuming a uniform lattice pitch. FIG. 1(a) shows the diffractive optical element in a plan view with straight lines indicating the diffraction grating array therein. FIG. 1(b) is a partial enlargement of a section of the diffractive optical element in FIG. 1(a) taken over a plane ranging perpendicular to the drawing sheet. FIG. 1(b) shows cyclical stage patterns with the individual stages assuming widths equal to one another. In the following description, the type of diffractive optical element shown in FIG. 1 is referred to as a linear grating-type diffractive optical element. FIG. 2 show a diffractive optical element with ring-shaped diffraction gratings arrayed coaxially with the lattice pitch gradually reduced for diffraction gratings further away from the coaxial center. FIG. 2(a) shows the diffractive optical element in a plan view with the diffraction grating array therein each indicated as a circumference. FIG. 2(a) is a sectional view of the diffractive optical element in FIG. 2(a) taken over a plane ranging through the coaxial center and perpendicular to the drawing sheet. FIG. 2(c) is a partial enlargement of FIG. 2(b). The section shown in FIG. 2(b) assumes a shape resembling the shape achieved by evenly slicing a plano-convex lens along its optical axis and then sequentially slicing off areas where the phase changes uniformly within the plane while sustaining the surface contour. The dotted lines in FIG. 2(c) indicate the curved surfaces in FIG. 2(b). FIG. 2(c) shows cyclical stage patterns that have been formed to approximate the curvature. In the following description, the type of diffractive optical element shown in FIG. 2 is referred to as a Fresnel lens type diffractive optical element. Methods that may be adopted when manufacturing linear grating type diffractive optical elements are explained in reference to the first through fourth embodiments, whereas a method that may be adopted when manufacturing Fresnel lens type diffractive optical elements is explained in reference to the fifth embodiment.

In the following explanation of the first through fourth embodiments, the width representing the cycle over which stages are formed is referred to as P, the width of a stage formed through the final process is referred to as L and the stage depth is referred to as D. The range of the cyclical width P, which is the lattice pitch P, is indicated by the one-point chain lines in the figures. It is assumed that all the stages have a uniform width L=P/k. k represents the number of stages, and, for instance, if the diffractive optical element has eight stage patterns, k=8. In addition, with H representing the height achieved with the entire set of stages, the stage depth is expressed as D=H/(k−1). It is to be noted that the uppermost stage is referred to as a first stage and the lower stages are sequentially referred to as the second stage, the third stage and so forth. It is to be noted that the substrate in the illustrations provided in the figures does not necessarily reflect its actual thickness accurately. In addition, in the illustrations of etching steps, an area where a groove is formed through etching is indicated by an arrow. In the following description, a etching target area or a non-etching area that ranges continuously within each lattice pitch P is regarded as a single etching target or non-etching area. For instance, an etching target area or a non-etching area ranging over a plurality of stages adjacent to each other is regarded to be a single etching target area or a single non-etching area as long as it maintains the continuity. For instance, the entire area covering the first stage through the sixth stage is designated as a non-etching area for the step shown in FIG. 3(9), as described later, and accordingly, this entire area is regarded as a single non-etching area.

The diffractive optical element manufacturing method achieved in the first embodiment of the present invention is now explained in reference to FIG. 3 and FIG. 4. FIG. 3 is a sectional view of the manufacturing steps executed in the diffractive optical element manufacturing method achieved in the first embodiment of the present invention, whereas FIG. 4 is a sectional view of steps executed after the step in FIG. 3(10). in reference to the embodiment, a method for manufacturing a seven-phase staged diffractive optical element assuming cyclically formed seven-stage patterns, is described. FIG. 4(10) shows the seven-stage pattern that is ultimately achieved, labeled with P, L, D and H explained earlier. The following explanation is given by assuming that the substrate is constituted of silicon and that the substrate is anisotropically dry etched during each etching step by engaging a reactive ion etching device (RIE device) in operation with an etching gas constituted with SF₆. In addition, each photolithography step is executed by using an i-line stepper and a standard positive resist.

FIGS. 3(1) through 3(5) show the steps executed during a first process in FIG. 2(c). First, as shown in FIG. 3(1), a resist 2 is applied onto a substrate 1. Next, as shown in FIG. 3(2), the substrate is exposed by using a mask 101. The mask 101 has four light shielding portions and three opening portions set within the lattice pitch P, with the light shielding portions and the opening portions each assuming a pattern width L. Next, the substrate is developed, thereby forming a resist pattern 121 shown in FIG. 3(3). The resist retaining areas and the resist removal areas in the resist pattern 121, too, each assume a pattern width L. Next, the substrate is etched by using the resist pattern 121, thereby forming the groove pattern, as shown in FIG. 3(4). The etching depth Dp₁ achieved through the first process is D. Namely, the areas to form the second stage, the fourth stage and the sixth stage are etched to the depth D, while the areas to form the first, third, fifth and seventh stages remain unetched. In other words, there are four non-etching areas and three etching target areas set within the lattice pitch P. Then, the resist pattern 121 is removed, thereby forming the grooves achieving the depth shown in FIG. 3(5). Through the first process described above, cyclical patterns constituted of recesses, each formed with a groove having the width L alternating with projections, are formed.

The operation then shifts into a second process. FIGS. 3(6) through 3(10) show the steps executed during the second process in FIG. 2(c). First, as shown in FIG. 3(6), the resist 2 is applied onto the substrate 1 with the grooves having been formed therein through the first process. Next, as shown in FIG. 3(7), the substrate is exposed by using a mask 102. The mask 102 has a single light shielding portion and a single opening portion set within the lattice pitch P, with the light shielding portion and the opening portion assuming pattern widths 6L and L respectively. Next, the substrate is developed, thereby forming a resist pattern 122 shown in FIG. 3(8). The resist retaining area and the resist removal area in the resist pattern 122, too, assume pattern widths 6L and L respectively. Next, the substrate is etched by using the resist pattern 122, thereby forming the groove pattern, as shown in FIG. 3(9). The etching depth Dp₂ achieved through the second process is 2D. Namely, the area to form the seventh stage is etched to the depth 2D, while the area to form the first through sixth stages remains unetched. In other words, a single non-etching area and a single etching target area are set within the lattice pitch P. Then, the resist pattern 122 is removed, thereby forming the grooves achieving the pattern shown in FIG. 3(10).

The operation then shifts into a third process. FIGS. 4(1) through 4(5) show the steps executed during the third process in FIG. 2(c). First, as shown in FIG. 4(1) the resist 2 is applied onto the substrate 1 with the groove pattern having been formed therein through the second process. Next, as shown in FIG. 4(2), the substrate is exposed by using a mask 103. The mask 103 has a single light shielding portion and a single opening portion set within the lattice pitch P, with the light shielding portion and the opening portion assuming pattern widths 4L and 3L respectively. Next, the substrate is developed, thereby forming a resist pattern 123 shown in FIG. 4(3). The resist retaining area and the resist removal area in the resist pattern 123, too, assume pattern widths 4L and 3L respectively. Next, the substrate is etched by using the resist pattern 123, thereby forming the groove pattern, as shown in FIG. 4(4). The etching depth Dp₃ achieved through the third process is 2D. Namely, the area to form the fifth through seventh stages is etched to the depth 2D, while the areas to form the first through fourth stages remain unetched. In other words, a single non-etching area and a single etching target area are set within the lattice pitch P. Then, the resist pattern 123 is removed, thereby forming the grooves achieving the depths shown in FIG. 4(5).

The operation then shifts into a fourth process. FIGS. 4(6) through 4(10) show the steps executed during the fourth process in FIG. 2(c). First, as shown in FIG. 4(6), the resist 2 is applied onto the substrate 1 with the grooves having been formed therein through the third process. Next, as shown in FIG. 4(7), the substrate is exposed by using a mask 104. The mask 104 has a single light shielding portion and a single opening portion set within the lattice pitch P, with the light shielding portion and the opening portion assuming pattern widths 2L and 5L respectively. Next, the substrate is developed, thereby forming a resist pattern 124 shown in FIG. 4(8). The resist retaining area and the resist removal areas in the resist pattern 124, too, assume pattern widths 2L and 5L respectively. Next, the substrate is etched by using the resist pattern 124, thereby forming the groove pattern, as shown in FIG. 4(9). The etching depth Dp₄ achieved through the fourth process is 2D. Namely, the areas to form the third through seventh stages is etched to the depth 2D, while the areas to form the first and second stages remains unetched. In other words, a single non-etching area and a single etching target area are set within the lattice pitch P. Then, the resist pattern 124 is removed, thereby forming a diffractive optical element with a seven-stage pattern, as shown in FIG. 4(10).

As described above, the opening portions assume pattern widths L, L, 3L and 5L in the masks used in the first, second, third and fourth processes respectively in the manufacturing method achieved in the embodiments. The pattern width for a later process is set equal to or greater than the pattern width set for the preceding process. In other words, as the processing phase advances, the pattern width increases through the second process and subsequent processes. In addition, as shown in FIGS. 3(7), 4(2) and 4(7), the light shielding portion and the opening portion within the lattice pitch P is separated at a single boundary in the second, third and fourth processes. While the exposure conditions for the exposure operations executed in the second, third and fourth processes are determined so as to ensure that the shape achieving the design value is formed over the boundary area, the boundary area is present only at a single location during the second, third and fourth processes. In other words, the optimal exposure conditions need to be set so as to minimize the error occurring at the single boundary area. Since only a single fixed set of optimal exposure conditions need to be determined, the desired groove pattern can be formed with a high level of accuracy. It is to be noted that while a plurality of boundaries separate the light shielding portions from the opening portions within the lattice pitch during the first process, the resist thickness is uniform during the first process and thus, the grooves can be formed without problem and with a high level of accuracy through a method of the known art.

In the method in the related art shown in FIG. 14, a plurality of boundaries separating the light shielding portions and the opening portions from each other are present within the lattice pitch P and the resist is applied over varying thicknesses, making it difficult to select common optimal exposure conditions that will achieve optimal exposure at all the boundary areas. This tends to result in the formation of projections or dimensional errors due to over/under exposure. This issue is effectively addressed in the embodiment. In other words, the stage patterns constituting the diffractive optical element can be formed with a high level of accuracy by adopting the embodiment, which, in turn, assures an improvement in the diffraction efficiency.

A seven-staged diffractive optical element with the lattice pitch set to 3.5 μm and the stage width set to 0.5 μm was actually manufactured through the method achieved in the embodiment. The diffractive optical element thus manufactured was verified to be a high-precision diffractive optical element with no projections formed at the edges of the stages, the stage width measured at 0.47 μm and the error of approximately 6%.

It is to be noted that an existing seven-phase staged diffractive optical element can be inspected to determine whether or not it was manufactured through the seven-phase staged diffractive optical element manufacturing method achieved in the embodiment of the present invention. In reference to FIGS. 5(a) and 5(b), two methods that may be adopted in such an inspection are explained. FIG. 5(a) shows the positional relationship of the stages in a seven-phase staged diffractive optical element manufactured on a substrate through the manufacturing method of the embodiment described above relative to the patterns in the masks 101, 102, 103 and 104 used during the manufacturing processes. FIG. 5(b) shows the positional relationship of the stages in the seven-phase staged diffractive optical element manufactured on a substrate as disclosed in patent reference literature 1 described above, relative to the patterns in the masks 21, 22 and 23 used during the manufacturing processes. The law of diffraction allows H to be expressed as in (1) below by using the wavelength λ of the diffracted light and the refractive index n of the substrate. In addition, D in a seven-phase staged diffractive optical element can be expressed as in (2) below.

$$\begin{matrix}H = \frac{6 λ}{7 ( n - 1 )} & ( 1 ) \\ D = \frac{λ}{7 ( n - 1 )} & ( 2 )\end{matrix}$$

As FIG. 5(a) indicates, the substrate surface is equivalent to the top of the highest stage among the stages in the diffractive optical element manufactured by adopting the method achieved in the first embodiment of the present invention. The difference Ha in height between the substrate surface S and the bottom of the lowest stage can be expressed as in (3) below.

$$Ha = \frac{6 λ}{7 ( n - 1 )} \qquad ( 3 )$$

As shown in FIG. 5(b), the substrate surface S is not equivalent to the top of the highest stage in the diffractive optical element manufactured through the method disclosed in patent reference literature 1. The difference Hb in height between the substrate surface and the bottom of the lowest stage can be expressed as in (4) below by using the wavelength λ of the diffracted light and the refractive index n of the substrate.

$$Hb = \frac{λ}{n - 1} \qquad ( 4 )$$

Accordingly, by measuring the height difference between the substrate surface and the bottom of the lowest stage in the diffractive optical element and referencing expressions (3) and (4), the manufacturing method having been adopted to manufacture the seven-phase diffractive optical system can be determined. This sequence constitutes the first inspection method.

Next, the second inspection method is described. In the description of the various processes provided above, the etching depths to which the substrate is etched by using the mask pattern 101, 102, 103 and 104 are indicated in units of the stage depth D. However, strictly speaking, the etching depths actually achieved contain minute errors attributable to various conditions and there is variance to be dealt with among various etching steps. With Ha₁, Ha₂, . . . Ha₆ representing the stage depths of the uppermost stage and downward as shown in FIG. 5(a), the stage depths of the individual stages in the diffractive optical element manufactured through the manufacturing method of the embodiment may be expressed as below. The term “stage depth” refers to the difference in height between the subject stage and the stage directly under the subject stage.

Ha₁=Dp₁

Ha₂=Dp₄−Dp₁

Ha₃=Dp₁

Ha₄=Dp₃−Dp₁

Ha₅=Dp₁

Ha₆=Dp₂−Dp₁

The expressions above indicate that Ha₁=Ha₃=Ha₅=Dp₁. Namely, the stage depths of the odd-numbered stages are invariably Dp₁.

With Hb₁, Hb₂, . . . Hb₆ representing the stage depths of the uppermost stage and downward as shown in FIG. 5(b), the stage depths of the individual stages in the seven-phase diffractive optical element manufactured through the manufacturing method in the related art may be expressed as below.

Hb₁=Dc₂−Dc₃

Hb₂=Dc₃

Hb₃=Dc₁−(Dc₂+Dc₃)

Hb₄=Dc₃

Hb₅=Dc₂−Dc₃

Hb₆=Dc₃

The expressions above indicate that Hb₂=Hb₄=Hb₆=Dc₃. Namely, the stage depths of the even-numbered stages are invariably Dc₃. Accordingly, by measuring the stage depths of the individual stages in the seven-phase staged diffractive optical element and referencing the relational expressions provided above, the specific manufacturing method having been adopted when manufacturing the seven-phase diffractive optical element can be determined. As described above, by measuring the difference in height between the substrate surface and the bottom of the lowest stage in the lattice or the stage depths of the stages in the lattice in the existing seven-phase staged diffractive optical element, it is possible to ascertain whether or not the seven-phase staged diffractive optical element was manufactured by adopting the technology according to the present invention.

Next, the diffractive optical element manufacturing method achieved in the second embodiment of the present invention is explained in reference to FIG. 6. FIG. 6 is a sectional view of the manufacturing steps executed in the diffractive optical element manufacturing method achieved in the second embodiment of the present invention. In reference to the embodiment, a method for manufacturing a nine-phase staged diffractive optical element assuming cyclically formed seven-stage patterns, is described. P, L and D used in the description provided below have definitions identical to those explained earlier in reference to the first embodiment and the explanation is given below by assuming that k=9. It is also assumed that the substrate is constituted of silicon and that the substrate is anisotropically dry etched during each etching step by engaging a reactive ion etching device (RIE device) in operation with an etching gas constituted with SF₆. In addition, each photolithography step is executed by using an i-line stepper and a standard positive resist.

A first process starts by applying a resist onto a substrate 1, as in the step shown in FIG. 3(1) executed in the first embodiment. Next, the substrate is exposed and developed by using a mask 201, thereby forming a resist pattern 221, as shown in FIG. 6(1). The mask 201 has five light shielding portions and four opening portions set within the lattice pitch P, with the light shielding portions and the opening portions each assuming a pattern width L. The resist retaining areas and the resist removal areas in the resist pattern 122, too, each assume a pattern width L. Next, the substrate is etched by using the resist pattern 221, thereby forming the groove pattern, as shown in FIG. 6(2). Namely, the areas to form the second stage, the fourth stage, the sixth stage and the eighth stage are etched to the depth D, while the areas to form the first, third, fifth, seventh and ninth stages remain unetched. In other words, there are five non-etching areas and four etching target areas set within the lattice pitch P. Then, the resist pattern 221 is removed. Through the first process described above, a cyclical pattern constituted of recesses, each formed with a groove having the width L alternating with projections, is formed.

The operation then shifts into a second process. First, the resist is applied onto the substrate with the grooves having been formed therein through the first process. Next, the substrate is exposed and developed by using a mask 202, thereby forming a resist pattern 222, as shown in FIG. 6(3). The mask 202 has one light shielding portion and one opening portion set within the lattice pitch P, with the light shielding portion and the opening portions assuming pattern widths 8L and L respectively. The resist retaining area and the resist removal area in the resist pattern 222, too, assume pattern widths 8L and L respectively. Next, the substrate is etched by using the resist pattern 222, thereby forming the groove portions shown in FIG. 6(4). Namely, the area to form the ninth stage is etched to the depth 2D, while the area to form the first through eighth stages remain unetched. In other words, a single non-etching area and a single etching target area are set within the lattice pitch P. Then, the resist pattern 222 is removed.

The operation then shifts into a third process. First, the resist is applied onto the substrate with the groove pattern having been formed therein through the second process. Next, the substrate is exposed and developed by using a mask 203, thereby forming a resist pattern 223, as shown in FIG. 6(5). The mask 203 has two light shielding portions and two opening portions set within the lattice pitch P, with the light shielding portions each assuming a pattern width of 2L and the pattern width of the upper stage-side opening portion and the pattern width of the lower stage-side opening portion respectively set to 2L and 3L. The resist retaining areas each assume a pattern width 2L, whereas the pattern width of the upper stage-side resist removal area and the pattern width of the lower stage-side resist removal area are set to 2L and 3L respectively. Next, the substrate is etched by using the resist pattern 223, thereby forming the groove pattern, as shown in FIG. 6(6). Namely, the areas to form the third and fourth stages and seventh through ninth stages are etched to the depth 2D, while the areas to form the first, second, fifth and sixth stages remain unetched. In other words, two non-etching areas and two etching target areas are set within the lattice pitch P. Then, the resist pattern 223 is removed.

The operation then shifts into a fourth process. First, the resist is applied onto the substrate with the groove pattern having been formed therein through the third process. Next, the substrate is exposed and developed by using a mask 204, thereby forming a resist pattern 224, as shown in FIG. 6(7). The mask 204 has one light shielding portion and one opening portion set within the lattice pitch P, with the light shielding portions and the opening portions assuming pattern widths 4L and 5L respectively. The resist retaining area and the resist removal area in the resist pattern 224, too, assume pattern widths 4L and 5L respectively. Next, the substrate is etched by using the resist pattern 224, thereby forming the groove pattern, as shown in FIG. 6(8). Namely, the area to form the fifth through ninth stages is etched to the depth 4D, while the area to form the first through fourth stages remains unetched. In other words, a single non-etching area and a single etching target area are set within the lattice pitch P. Then, the resist pattern 224 is removed, thereby forming a diffractive optical element with a nine-stage pattern.

This embodiment, too, allows the stage patterns to constitute the diffractive optical element to be formed with a high level of accuracy, as does the first embodiment, assuring an improvement in the diffraction efficiency. A nine-staged diffractive optical element with the lattice pitch set to 4.5 μm and the stage width set to 0.5 μm was actually manufactured through the method achieved in the embodiment. The diffractive optical element thus manufactured was verified to be a high-precision diffractive optical element with no projections formed at the edges of the stages, the stage width measured at 0.48 μm and the error amounting to approximately 4%.

Next, the diffractive optical element manufacturing method achieved in the third embodiment of the present invention is explained in reference to FIG. 7. FIG. 7 is a sectional view of the manufacturing steps executed in the diffractive optical element manufacturing method achieved in the third embodiment of the present invention. In reference to the embodiment, a method for manufacturing an eight-phase staged diffractive optical element assuming a cyclically formed seven-stage pattern. P, L and D used in the description provided below have definitions identical to those explained earlier in reference to the first embodiment and the explanation is given below by assuming that k=8. The following explanation is given by assuming that the substrate is constituted of silicon and that the substrate is anisotropically dry etched during each etching step by engaging a reactive ion etching device (RIE device) in operation with an etching gas constituted with SF₆. In addition, each photolithography step is executed by using an i-line stepper and a standard positive resist.

A first process starts by applying a resist onto a substrate 1, as in the step shown in FIG. 3(1) executed in the first embodiment. Next, the substrate is exposed and developed by using a mask 301, thereby forming a resist pattern 321, as shown in FIG. 7(1). The mask 301 has four light shielding portions and four opening portions set within the lattice pitch P, with the light shielding portions and the opening portions each assuming a pattern width L. The resist retaining areas and the resist removal areas in the resist pattern 321, too, each assume a pattern width L. Next, the substrate is etched by using the resist pattern 321, thereby forming the groove pattern, as shown in FIG. 7(2). Namely, the areas to form the second stage, the fourth stage, the sixth stage and the eighth stage are etched to the depth D, while the areas to form the first, third, fifth and seventh stages remain unetched. In other words, there are four non-etching areas and four etching target areas set within the lattice pitch P. Then, the resist pattern 321 is removed. Through the first process described above, a cyclical pattern constituted of recesses formed with a groove having the width L alternating with projections, is formed.

The operation then shifts into the second process. First, the resist is applied onto the substrate with the grooves having been formed therein through the first process. Next, the substrate is exposed and developed by using a mask 302, thereby forming a resist pattern 322, as shown in FIG. 7(3). The mask 302 has one light shielding portion and one opening portion set within the lattice pitch P, with the light shielding portion and the opening portion assuming pattern widths 6L and 2L respectively. The resist retaining area and the resist removal area in the resist pattern 322, too, assuming pattern widths 6L and 2L respectively. Next, the substrate is etched by using the resist pattern 322, thereby forming the groove pattern shown in FIG. 7(4). Namely, the area to form the seventh and eighth stages is etched to the depth 2D, while the area to form the first through sixth stages remains unetched. In other words, a single non-etching area and a single etching target area are set within the lattice pitch P. Then, the resist pattern 322 is removed.

The operation then shifts into a third process. First, the resist is applied onto the substrate with the groove pattern having been formed therein through the second process. Next, the substrate is exposed and developed by using a mask 303, thereby forming a resist pattern 323, as shown in FIG. 7(5). The mask 303 has one light shielding portion and one opening portion set within the lattice pitch P, with the pattern width of the light shielding portion and the opening portion each set to 4L. The pattern widths of the resist retaining area and the resist removal area in the resist pattern 323, too, are each set to 4L. Next, the substrate is etched by using the resist pattern 323, thereby forming the groove pattern, as shown in FIG. 7(6). Namely, the area to form the fifth through eighth stages is etched to the depth 2D, while the areas to form the first through fourth stages remains unetched. In other words, one non-etching area and one etching target area are set within the lattice pitch P. Then, the resist pattern 323 is removed.

The operation then shifts into a fourth process. First, the resist is applied onto the substrate with the groove pattern having been formed therein through the third process. Next, the substrate is exposed and developed by using a mask 304, thereby forming a resist pattern 324, as shown in FIG. 7(7). The mask 304 has one light shielding portion and one opening portion set within the lattice pitch P, with the light shielding portion and the opening portion assume pattern widths 2L and 6L respectively. The resist retaining area and the resist removal area in the resist pattern 324, too, assume pattern widths 2L and 6L respectively. Next, the substrate is etched by using the resist pattern 324, thereby forming the groove pattern shown in FIG. 7(8). Namely, the area to form the third through eighth stages is etched to the depth 2D, while the area to form the first and second stages remains unetched. In other words, a single non-etching area and a single etching target area are set within the lattice pitch P. Then, the resist pattern 324 is removed, thereby forming a diffractive optical element with an eight-stage pattern.

This embodiment, too, allows the stage patterns to constitute the diffractive optical element to be formed with a high level of accuracy, as does the first embodiment, assuring an improvement in the diffraction efficiency. An eight-staged diffractive optical element with the lattice pitch set to 4.0 μm and the stage width set to 0.5 μm was actually manufactured through the method achieved in the embodiment. The diffractive optical element thus manufactured was verified to be a high-precision diffractive optical element with no projections formed at the edges of the stages, the stage width measured at 0.47 μm and the error amounting to approximately 6%.

Next, the diffractive optical element manufacturing method achieved in the fourth embodiment of the present invention is explained in reference to FIG. 8. FIG. 8 is a sectional view of the manufacturing steps executed in the diffractive optical element manufacturing method achieved in the fourth embodiment of the present invention. In reference to the embodiment, a method for manufacturing a five-phase staged diffractive optical element assuming cyclically formed five-stage patterns, is described. P, L and D used in the description provided below have definitions identical to those explained earlier in reference to the first embodiment and the explanation is given below by assuming that k=5. It is also assumed that the substrate is constituted of silicon and that the substrate is anisotropically dry etched during each etching step by engaging a reactive ion etching device (RIE device) in operation with an etching gas constituted with SF₆. In addition, each photolithography step is executed by using an i-line stepper and a standard positive resist.

A first process starts by applying a resist onto a substrate 1, as in the step shown in FIG. 3(1) executed in the first embodiment. Next, the substrate is exposed and developed by using a mask 401, thereby forming a resist pattern 421, as shown in FIG. 8(1). The mask 401 has three light shielding portions and two opening portions set within the lattice pitch P, with the light shielding portions and the opening portions each assuming a pattern width L. The resist retaining areas and the resist removal areas in the resist pattern 421, too, each assume a pattern width L. Next, the substrate is etched by using the resist pattern 421, thereby forming the groove pattern, as shown in FIG. 8(2). Namely, the areas to form the second and fourth stages are etched to the depth D, while the areas to form the first, third and fifth stages remain unetched. In other words, there are three non-etching areas and two etching target areas set within the lattice pitch P. Then, the resist pattern 321 is removed. Through the first process described above, cyclical patterns constituted of recesses each formed with a groove having the width L, alternating with projections, are formed.

The operation then shifts into a second process. First, the resist is applied onto the substrate with the grooves having been formed therein through the first process. Next, the substrate is exposed and developed by using a mask 402, thereby forming a resist pattern 422, as shown in FIG. 8(3). The mask 402 has one light shielding portion and one opening portion set within the lattice pitch P, with the light shielding portion and the opening portion assuming pattern widths 4L and L respectively. The resist retaining area and the resist removal area in the resist pattern 422, too, assuming pattern widths 4L and L respectively. Next, the substrate is etched by using the resist pattern 422, thereby forming the groove pattern shown in FIG. 8(4). Namely, the area to form the fifth stage is etched to the depth 2D, while the area to form the first through fourth stages remain unetched. In other words, a single non-etching area and a single etching target area are set within the lattice pitch P. Then, the resist pattern 422 is removed.

The operation then shifts into a third process. First, the resist is applied onto the substrate with the groove pattern having been formed therein through the second process. Next, the substrate is exposed and developed by using a mask 403, thereby forming a resist pattern 423, as shown in FIG. 8(5). The mask 403 has one light shielding portion and one opening portion set within the lattice pitch P, with the pattern widths of the light shielding portion and the opening portion set to 2L and 3L respectively. The pattern widths of the resist retaining area and the resist removal area in the resist pattern 423, too, are set to 2L and 3L respectively. Next, the substrate is etched by using the resist pattern 423, thereby forming the groove pattern shown in FIG. 8(6). Namely, the area to form the third, fourth and fifth stages is etched to the depth 2D, while the area to form the first and second stages remain unetched. In other words, one non-etching area and one etching target area are set within the lattice pitch P. Then, the resist pattern 423 is removed, thereby forming a diffractive optical element with five-stage patterns. This embodiment, too, allows the stage patterns to constitute the diffractive optical element to be formed with a high level of accuracy, as does the first embodiment, assuring an improvement in the diffraction efficiency.

Next, methods that may be adopted when manufacturing Fresnel lens type diffractive optical elements are explained in reference to the fifth embodiment and a variation thereof. The diffractive optical element manufacturing method achieved in the fifth embodiment of the present invention is explained in reference to FIG. 9 and FIG. 10. FIG. 9 is a sectional view of the manufacturing steps executed in the diffractive optical element manufacturing method achieved in the fifth embodiment of the present invention, whereas FIG. 10 is a sectional view of steps executed after the step in FIG. 9. In reference to the embodiment, a method for manufacturing a Fresnel lens type seven-phase staged diffractive optical element assuming a cyclically formed seven-stage patterns, is described. FIG. 10(4) shows a seven-stage pattern that is ultimately achieved. Since the stage patterns in a Fresnel lens type diffractive optical element are formed by approximating a curved surface, the stage width set within the lattice pitch are not uniform, and the stage width gradually becomes smaller as the curvature of the curved surface to which the staged pattern is approximated becomes steeper. The diffractive optical element formed by adopting the embodiment may be regarded to be a variation of that formed through the first embodiment with varying stage widths.

In the following explanation of the fifth embodiment and the variation thereof, the width representing each cycle over which a set of stages is formed is referred to as P, and the stage depth is referred to as D. The range of the cyclical width P, which is the lattice pitch P, is indicated by the one-point chain lines in the figures. In addition, the uppermost stage is referred to as a first stage and the lower stages are sequentially referred to as the second stage, the third stage and so forth. It is to be noted that the substrate in the illustrations provided in the figures does not necessarily reflect its actual thickness accurately. In addition, in the illustrations of etching steps, an area where a groove is formed through etching is indicated by an arrow. In the following description, the definition of a single etching target area or a non-etching area is identical to that of the first through fourth embodiment. The following explanation is given by assuming that the substrate is constituted of silicon and that the substrate is anisotropically dry etched during each etching step by engaging a reactive ion etching device (RIE device) in operation with an etching gas constituted with SF₆. Also, each photolithography step is executed by using an i-line stepper and a standard positive resist.

A first process starts by applying a resist onto a substrate 1, as in the step shown in FIG. 3(1) executed in the first embodiment. Next, the substrate is exposed and developed by using a mask 501, thereby forming a resist pattern 521, as shown in FIG. 9(1). The mask 501 has four light shielding portions and three opening portions set within the lattice pitch P. Next, the substrate is etched by using the resist pattern 521, thereby forming the groove pattern, as shown in FIG. 9(2). Namely, the areas to form the second, fourth and sixth stages are etched to the depth D, while the areas to form the first, third, fifth and seventh stages remain unetched. In other words, there are four non-etching areas and three etching target areas set within the lattice pitch P. Then, the resist pattern 521 is removed. Through the first process described above, cyclical patterns constituted of recesses each formed with a groove having the width L alternating with projections, are formed.

The operation then shifts into a second process. First, the resist is applied onto the substrate with the grooves having been formed therein through the first process. Next, the substrate is exposed and developed by using a mask 502, thereby forming a resist pattern 522, as shown in FIG. 9(3). The mask 502 has one light shielding portion and one opening portion set within the lattice pitch P. Next, the substrate is etched by using the resist pattern 522, thereby forming the groove pattern, as shown in FIG. 9(4). Namely, the area to form the seventh stage is etched to the depth 2D, while the area to form the first through sixth stages remains unetched. In other words, a single non-etching area and a single etching target area are set within the lattice pitch P. Then, the resist pattern 522 is removed.

The operation then shifts into the third process. First, the resist is applied onto the substrate with the groove pattern having been formed therein through the second process. Next, the substrate is exposed and developed by using a mask 503, thereby forming a resist pattern 523, as shown in FIG. 9(5). The mask 503 has one light shielding portion and one opening portion set within the lattice pitch P. Next, the substrate is etched by using the resist pattern 523, thereby forming the groove pattern, as shown in FIG. 10(1). Namely, the area to form the fifth through seventh stages is etched to the depth 2D, while the area to form the first through fourth stages remains unetched. In other words, a single non-etching area and a single etching target area are set within the lattice pitch P. Then, the resist pattern 523 is removed.

The operation then shifts into a fourth process. First, the resist is applied onto the substrate with the groove pattern having been formed therein through the third process. Next, the substrate is exposed and developed by using a mask 504, thereby forming a resist pattern 524, as shown in FIG. 10(2). The mask 504 has one light shielding portion and one opening portion set within the lattice pitch P. Next, the substrate is etched by using the resist pattern 524, thereby forming the groove pattern, as shown in FIG. 10(3). Namely, the area to form the third through seventh stages is etched to the depth 2D, while the area to form the first and second stages remains unetched. In other words, a single non-etching area and a single etching target area are set within the lattice pitch P. Then, the resist pattern 524 is removed, thereby forming a Fresnel lens type diffractive optical element with seven-stage patterns, as shown in FIG. 10(4).

This embodiment, too, allows the stage patterns to constitute the diffractive optical element to be formed with a high level of accuracy, as does the first embodiment, assuring an improvement in the diffraction efficiency. Through the method achieved in the embodiment, a Fresnel lens type diffractive optical element assuming stage patterns approximating a specific curved surface can be formed in a manner similar to the first embodiment simply by adjusting the mask pattern widths in the first embodiment. It is to be noted that a Fresnel lens type diffractive optical element with a number of stages other than seven may be also formed through a similar method simply by adjusting the mask pattern widths.

The table below lists the numbers of non-etching areas and etching target areas set for the individual processes executed in the manufacturing methods in the first through fifth embodiments described above and in manufacturing methods in the related art. Related art example 1 and related art example 2 in the table respectively correspond to the methods for forming the eight-stage patterns and the seven-stage patterns having been explained as the background art in this specification. The definition of a single etching target area or a non-etching area assumed for these related art examples is identical to that having been explained in reference to the first through fifth embodiment.

TABLE 1

| | | FIRST | SECOND | THIRD | FOURTH |
|---|---|---|---|---|---|
| | | PROCESS | PROCESS | PROCESS | PROCESS |
| FIRST | NON-ETCHING AREAS | 4 | 1 | 1 | 1 |
| EMBODIMENT | ETCHING TARGET | 3 | 1 | 1 | 1 |
| (SEVEN STAGES) | AREAS | | | | |
| SECOND | NON-ETCHING AREAS | 5 | 1 | 2 | 1 |
| EMBODIMENT | ETCHING TARGET | 4 | 1 | 2 | 1 |
| (NINE STAGES) | AREAS | | | | |
| THIRD | NON-ETCHING AREAS | 4 | 1 | 1 | 1 |
| EMBODIMENT | ETCHING TARGET | 4 | 1 | 1 | 1 |
| (EIGHT STAGES) | AREAS | | | | |
| FOURTH | NON-ETCHING AREAS | 3 | 1 | 1 | |
| EMBODIMENT | ETCHING TARGET | 2 | 1 | 1 | |
| (FIVE STAGES) | AREAS | | | | |
| FIFTH | NON-ETCHING AREAS | 4 | 1 | 1 | 1 |
| EMBODIMENT | ETCHING TARGET | 3 | 1 | 1 | 1 |
| (SEVEN STAGES) | AREAS | | | | |
| RELATED ART | NON-ETCHING AREAS | 1 | 2 | 4 | |
| EXAMPLE 1 | ETCHING TARGET | 1 | 2 | 4 | |
| (EIGHT STAGES) | AREAS | | | | |
| RELATED ART | NON-ETCHING AREAS | 1 | 2 | 3 | |
| EXAMPLE 2 | ETCHING TARGET | 1 | 2 | 4 | |
| (SEVEN STAGES) | AREAS | | | | |

As the table indicates, with k representing the number of stages formed through the manufacturing methods achieved in the first through fifth embodiments of the present invention, the numbers of etching target areas and non-etching areas in a single cycle range (the range corresponding to the lattice pitch P) set for the first process are both k/2 provided that k is an even number but are respectively (k−1)/2 and (k+1)/2 if k is an odd number. The numbers of etching target areas and non-etching areas in the single cycle range set for the second process are both smaller than the corresponding numbers set for the first process. It is worth noting that the numbers of etching target areas and non-etching areas set in the single cycle range for the second process and subsequent processes are both one in the manufacturing methods achieved in the first and third through fifth embodiments. In contrast, the numbers of etching target areas and non-etching areas set for the first process are both one and the numbers sequentially increase for the second process onward in the manufacturing methods in the related art.

The numbers of etching target areas and non-etching areas directly correspond to the numbers of resist removal areas and resist retaining areas. In the manufacturing method achieved in any of the embodiments of the present invention, the numbers of resist removal areas and resist retaining areas set within the single cycle range are at their greatest during the first process and smaller numbers of resist removal areas and resist retaining areas are set in the subsequent processes. This means that the number of boundaries separating the resist removal areas from the resist retaining areas is at its greatest during the first process and becomes smaller for subsequent processes. Namely, according to the present invention, the number of boundaries separating the resist removal areas from the resist retaining areas, over which an error tends to occur readily is reduced in the later steps in which the variance among the resist thicknesses among the individual stages becomes more pronounced. As a result, the error is reduced and a diffractive optical element assuming stage patterns can be manufactured with a high level of accuracy by adopting any of the manufacturing methods achieved in the embodiment of the present invention, diffractive optical elements assuming a staged pattern can be manufactured with a high level of accuracy. In particular, in the manufacturing methods achieved in the first and third through fifth embodiments, there is only one boundary area separating the resist removal area from the resist retaining area set for the second and subsequent processes through which more stages are formed. Since there is only one area where the resist pattern error factor needs to be taken into consideration and the exposure conditions can be determined simply to prevent an error from occurring over this specific area, optimal conditions can be set with ease.

Next, the diffractive optical element manufacturing method achieved as a variation of the fifth embodiment is explained in reference to FIG. 11. FIG. 11 shows the steps executed in the diffractive optical element manufacturing method in the variation in FIG. 2(c). In the manufacturing method achieved in the variation, a Fresnel lens type diffractive optical element with seven-stage patterns, such as that shown in FIG. 10(4) is manufactured by switching the order in which the first process and the second process are executed in the fifth embodiment. The following explanation focuses on the difference from the fifth embodiment and a repeated explanation of some of the elements of the variation identical to those of the fifth embodiment is omitted.

A first process starts by applying a resist onto a substrate 1, as in the step shown in FIG. 3(1) executed in the first embodiment. Next, the substrate is exposed and developed by using a mask 601, thereby forming a resist pattern 621, as shown in FIG. 11(1). Next, the substrate is etched by using the resist pattern 621, thereby forming the groove pattern shown in FIG. 11 (2). Namely, the area to form the seventh stage is etched to the depth 2D. The area to form the lowest stage, i.e., the seventh stage, assumes a smallest width within the lettuce pitch P. The resist pattern 621 is then removed.

The operation then shifts into a second process. First, the resist is applied onto the substrate with the groove pattern having been formed therein through the first process. Next, the substrate is exposed and developed by using a mask 602, thereby forming a resist pattern 622, as shown in FIG. 11(3). Next, the substrate is etched by using the resist pattern 622, thereby forming the groove pattern, as shown in FIG. 11(4). Namely, the areas to form the second, fourth and sixth stages are etched to the depth D. Then, the resist pattern 622 is removed. The groove pattern having been formed at the substrate 1 at this point is identical to that shown in FIG. 9(4). Accordingly, the operation shifts into the third process in the fifth embodiment, and subsequently, the substrate is processed as has been explained in reference to FIGS. 9(5) and 10(1) through 10(3) to obtain a Fresnel lens diffractive optical element with seven-stage patterns, as shown in FIG. 10(4), through the variation.

The variation is characterized in that the lowermost stage with a smallest width is formed through etching in the first process. Generally speaking, the overall depth of the stage pattern increases and the difference among the thicknesses of the resist applied at the individual stages becomes more pronounced in later processes. For this reason, it becomes more difficult to define the smallest pattern width with a high level of accuracy in later processes. Since the resist applied to the flat substrate surface at the start of the first process assumes a uniform resist thickness, it is easier to accurately define the smallest pattern width in this phase. In the manufacturing method achieved in the variation, the area to assume the smallest pattern width is processed through the first process and, as a result, the smallest pattern width can be defined with a high level of accuracy with ease.

It is to be noted that the method achieved in the variation by switching the order in which the first process and the second process are executed in the fifth embodiment can be adopted in the first embodiment when manufacturing a diffractive optical element with a seven-stage patterns. The method achieved in the variation can also be adopted in the fourth and second embodiments respectively related to formation of five-stage patterns and nine-stage patterns, by switching the order in which the first process and the second process are executed. Moreover, the method achieved in the variation may be adopted when manufacturing Fresnel lens type diffractive optical elements with five-stage patterns and nine-stage patterns by adjusting the pattern widths set in the fourth embodiment and the second embodiment respectively.

While the invention has been particularly shown and described with respect to preferred embodiments thereof by referring to the attached drawings, the present invention is not limited to these examples and it will be understood by those skilled in the art that various changes in form and detail may be made therein without departing from the spirit, scope and teaching of the invention.

While a substrate constituted of Si is processed by using an etching gas constituted with SF₆ in the first through fourth embodiment, any other material that can be used as a lens, such as GaAs, InP or quartz may be processed by using a corresponding type of etching gas with which the material can be anisotropically etched. For instance, a substrate constituted of Si may be processed by using an etching gas constituted with C4F8, CBrF3, CF4+O2, Cl2, SiCl4+Cl2, SF6+N2+Ar or BCl2+Cl2+Ar, a substrate constituted of poly-Si may be processed by using an etching gas constituted with Cl2, Cl2+HBr, Cl2+O2, CF4+O2, SF6, Cl2+N2, Cl2+HCl or HBr+Cl2+SF6, a substrate constituted of Si3N4 may be processed by using an etching gas constituted with CF4, CF4+O2, CF4+H2, CHF3+O2, C2F6, CHF3+O2+CO2 or CH2+F2+CF4, a substrate constituted of SiO2 may be processed by using an etching gas constituted with CF4, C4F8+O2+Ar, C5F8+O2+Ar, C3F6+O2+Ar, C4F8+CO, CHF3+O2 or CF4+H2, a substrate constituted of Al may be processed by using an etching gas constituted with BCl3+Cl2, BCl3+CHF3+Cl2, BCl3+CH2+Cl2, B+Br3+Cl2, BCl3+Cl2+N2 or SiO4+Cl2, a substrate constituted of Cu may be processed by using an etching gas constituted with Cl2, SiCl4+Cl2+N2+NH3, SiCl4+Ar+N2, BCl3+SiCl4+N2+Ar or BCl3+N2+Ar, a substrate constituted of Ta2O5 may be processed by using an etching gas constituted with CF4+H2+O2, a substrate constituted of TiN may be processed by using an etching gas constituted with CF4+O2+H2+NH3, C2F6+CO, CH3F+CO2, BC3+Cl2+N2 or CF4 and a substrate constituted of SiOF may be processed by using an etching gas constituted with CF4+CF4F8+CO+Ar.

In addition, while the resist patterns are formed by using mask patterns in the embodiments described above, the present invention is not limited to this example and resist patterns may be formed by directly drawing patterns with electron beams instead. In addition, a negative type resist instead of the positive type resist may be used. The patterns in masks formed by using negative type resist will be a reversal of the mask patterns having been described earlier in reference to the embodiments. The photolithography steps may be executed by adopting another type of lithography methods such as x-ray lithography, instead of by utilizing an i-line stepper. It is to be noted that the Fresnel lens type diffractive optical element manufactured as described above may be utilized as, for instance, a laser collimator lens in optical communication or a condenser lens in a photodiode.

### INDUSTRIAL APPLICABILITY

The present invention may be adopted in a method through which a diffractive optical element with cyclical stage patterns is manufactured and, more specifically, it may be adopted in a method for manufacturing a diffractive optical element to function as a lens element.

1. A method for manufacturing a diffractive optical element with seven stage patterns through a process of repeatedly etching the surface of a substrate by using a resist pattern, comprising:
a first step in which an area to form a second stage, a fourth stage and a sixth stage are etched to a first depth representing a stage depth;
a second step in which an area to form a lowest stage is etched to a depth twice said first depth;
a third step in which an area to form a fifth stage, the sixth stage and the seventh stage is etched to a depth twice said first depth; and
a fourth step in which an area to form the third stage, the fourth stage, the fifth stage, the sixth stage and the seventh stage is etched to a depth twice said first depth.

2. A method for manufacturing a diffractive optical element with nine stage patterns through a process of repeatedly etching the surface of a substrate by using a resist pattern, comprising:
a first step in which an area to form a second stage, a fourth stage, a sixth stage and an eighth stage are etched to a first depth representing a stage depth;
a second step in which an area to form a lowest stage is etched to a depth twice said first depth;
a third step in which an area to form a third stage, the fourth stage, a seventh stage, the eighth stage and the ninth stage is etched to a depth twice said first depth; and
a fourth step in which an area to form a fifth stage, the sixth stage, the seventh stage, the eighth stage and the ninth stage is etched to a depth four times said first depth, is provided.

3. A method for manufacturing a diffractive optical element with eight stage patterns through a process of repeatedly etching the surface of a substrate by using a resist pattern, comprising:
a first step in which an area to form a second stage, a fourth stage, a sixth stage and an eighth stage are etched to a first depth representing a stage depth;
a second step in which an area to form a seventh stage and the eighth stage is etched to a depth twice said first depth;
a third step in which an area to form a fifth stage, the sixth stage, the seventh stage and the eighth stage is etched to a depth twice said first depth; and
a fourth step in which an area to form a third stage, the fourth stage, the fifth stage, the sixth stage, the seventh stage and the eighth stage is etched to a depth twice said first depth.

4. A method for manufacturing a diffractive optical element with five stage patterns through a process of repeatedly etching the surface of a substrate by using a resist pattern, comprising:
a first step in which an area to form a second stage and a fourth stage are etched to a first depth representing a stage depth;
a second step in which an area to form a lowest stage is etched to a depth twice said first depth; and
a third step in which an area to form a third stage, the fourth stage and a fifth stage is etched to a depth twice said first depth.

5. A method for manufacturing a diffractive optical element with seven stage patterns through a process of repeatedly etching the surface of a substrate by using a resist pattern, comprising:
a first step in which an area to form a lowest stage is etched to a first depth twice the stage depth;
a second step in which an area to form a second stage, a fourth stage and a sixth stage are etched to a second depth matching said stage depth;
a third step in which an area to form a fifth stage, the sixth stage and a seventh stage is etched to said first depth; and
a fourth step in which an area to form a third stage, the fourth stage, the fifth stage, the sixth stage and the seventh stage is etched to said first depth, is provided.

6. A method for manufacturing a diffractive optical element with nine stage patterns through a process of repeatedly etching the surface of a substrate by using a resist pattern, comprising:
a first step in which an area to form a lowest stage is etched to a first depth twice the stage depth;
a second step in which an area to form a second stage, a fourth stage, a sixth stage and an eighth stage are etched to a second depth matching said stage depth;
a third step in which an area to form a third stage, the fourth stage, a seventh stage, the eighth stage and a ninth stage is etched to said first depth; and
a fourth step in which an area to form a fifth stage, the sixth stage, the seventh stage, the eighth stage and the ninth stage is etched to a depth twice said first depth.

7. A method for manufacturing a diffractive optical element with five stage patterns through a process of repeatedly etching the surface of a substrate by using a resist pattern, comprising:
a first step in which an area to form a lowest stage is etched to a first depth twice the stage depth;
a second step in which an area to form a second stage and a fourth stage are etched to a second depth matching said stage depth; and
a third step in which an area to form a third stage, the fourth stage and the fifth stage is etched to said first depth.

8. A method for manufacturing a diffractive optical element having a cyclical stage pattern with k (k represents a natural number equal to or greater than 2) stages through a process of repeatedly etching the surface of a substrate by using a resist pattern, wherein:
the number of etching target areas and the number of non-etching areas set in a single cycle area for a first process are both k/2 if k is an even number, but the number of etching target areas and the number of non-etching areas set in said single cycle area for said first process are respectively (k−1)/2 and (k+1)/2 if k is an odd number; and
the number of etching target areas to be etched and the number of non-etching areas set in said single cycle area for a second process or a subsequent process are both smaller than the number of etching target areas and the number of non-etching areas set for said first process.

9. A method for manufacturing a diffractive optical element according to claim 8, wherein:
the number of etching target areas and the number of non-etching areas set in said single cycle area for said second process and subsequent processes are both one.

10. A method for manufacturing a diffractive optical element assuming a cyclical stage patterns through a process of etching the surface of a substrate repeatedly by using a resist pattern, wherein:
pattern widths set for etching target areas in a single cycle area for a first process are substantially equal to a smallest stage width.

11. A method for manufacturing a diffractive optical element according to claim 1, wherein:
the substrate is anisotropically etched.

12. A method for manufacturing a diffractive optical element according to claim 1, wherein:
the substrate is constituted of silicon, quartz, GaAs or InP.
